(19) United States
(12) Patent Application Publication
(10) Pub. No.: US 2026/0006948 A1
(43) Pub. Date: Jan. 1, 2026

(54) MESA POROSIFICATION PROCESS

(71) Applicant: Commissariat à I'Énergie Atomique et aux Énergies Alternatives, Paris (FR)

(72) Inventors: Carole Pernel, Grenoble (FR); Margaux Audibert, Grenoble (FR); Valentin Vivares, Grenoble (FR)

(73) Assignee: Commissariat à I'Énergie Atomique et aux Énergies Alternatives, Paris (FR)

(21) Appl. No.: 19/248,780

(22) Filed: Jun. 25, 2025

(30) Foreign Application Priority Data
Jun. 27, 2024 (FR) FR2406898

(51) Int. Cl. H10H 20/818; H10H 20/01; H10H 20/825

(52) U.S. Cl. CPC H10H 20/818; H10H 20/0137; H10H 20/825

(57) ABSTRACT

A process for porosifying a structure including a base substrate covered with mesas, the mesas being (Al, In, Ga)N or InP mesas or (Al, In, Ga)N/(Al, In, Ga)N or InP/InP mesas, the mesas being electrochemically porosified according to the following cycle of steps: i) applying a first potential for a first duration, ii) applying a second potential for a second duration, whereby porosified mesas are obtainedincluding, from the side faces of the mesas towards the center of the mesas or vice versa, a first portion having a first porosification ratio and a second portion, the second portion having a second porosification ratio higher than the first porosification ratio or the second portion being hollowed out.

### CROSS REFERENCE TO RELATED APPLICATIONS

This application claims priority to French application number FR2406898, filed Jun. 27, 2024. The contents of this application is incorporated by reference in its entirety.

### TECHNICAL FIELD

The present description relates generally to the field of micro-LED-based color microdisplays.

The invention concerns a process for porosifying mesas, for example (Al, In, Ga)N/(Al, In, Ga)N mesas or InP/InP mesas.

The invention also concerns a structure thus obtained comprising porosified mesas.

### BACKGROUND ART

Color microdisplays comprise pixels made up of blue, green and red sub-pixels (RGB pixels). In the remainder of this description, these sub-pixels will be referred to simply as pixels, for the sake of brevity.

Blue and green pixels can be made from nitride materials, and red pixels from phosphide materials. To combine these three types of pixel on the same substrate, the “pick and place” technique is generally used. However, in the case of microdisplays with pixels smaller than 10 μm and/or displays with a large number of pixels (high definition), this technique can no longer be used due to alignment problems and/or the time required to implement it. In addition, pixels have to be taken from different ‘wafer’ plates, necessitating successive transfers. Parallel transfer techniques can also be used (‘mass transfer’).

Alternatively, color conversion can be achieved using quantum dots (QDs) or nanophosphors pumped by blue u LEDs from a single wafer, either transferred or in a monolithic matrix (preferred for microdisplays). However, it is difficult to control the deposition of these materials on small pixels, and their flux resistance is not sufficiently robust.

One solution is to form the three RGB pixels natively with the same family of materials, so that they can be grown on the same substrate. InGaN is the most promising material for this purpose. Theoretically, this material can cover the entire visible spectrum, depending on its indium concentration. Blue micro-LEDs based on InGaN already show high luminance, far superior to their organic counterparts. To emit at wavelengths in the green, the LED's quantum wells (PQs) must contain at least 25% indium, and for emission in the red, at least 35% indium is required. Unfortunately, the quality of InGaN material above 20% In is degraded by the low miscibility of InN in GaN, but also by the high compressive stress inherent in the growth of the InGaN active zone on GaN.

It is therefore essential to be able to reduce the overall stress in GaN/InGaN-based structures.

Currently, one of the most promising solutions is to porosify the GaN layer of mesas electrochemically by applying a potential for a set period of time. The porosified GaN layer thus obtained can be used to grow an InGaN-based LED nitride structure of better crystalline quality, thanks to the relaxation of the porous mesas generated.

However, it has been observed that epitaxy restarts by chemical vapor deposition from metal-organic precursors (MOCVD) on porous InGaN/GaN mesas seem to be disrupted by the presence of porosity on the mesa flanks. A layer of “liner” must therefore be deposited on the flanks to “neutralize” the porosity and prevent epitaxy on the flanks. However, as the pitch decreases, or as the inter-mesa distance decreases, depositing the liner layer becomes more delicate.

### SUMMARY OF INVENTION

There is a need for a method of manufacturing a device comprising porous mesas, such that an epitaxy can be easily carried out on the resulting mesas.

This aim is achieved by a process for porosifying a structure comprising a base substrate coated with mesas, the mesas being (Al, In, Ga)N or InP mesas or (Al, In, Ga)N/(Al, In, Ga)N or InP/InP mesas, the mesas being electrochemically porosified according to the following cycle of steps:
i) applying a first potential for a first duration,
ii) applying a second potential for a second duration,
   whereby porosified mesas are obtained comprising, from the side faces of the mesas towards the center of the mesas or vice versa, a first portion having a first porosification ratio and a second portion, the second portion having a second porosification ratio higher than the first porosification ratio or the second portion being hollowed out.

In a particular embodiment, the first potential is lower than the second potential.

According to a particular embodiment, the first potential is between 3 V and 12 V and/or the second potential is between 5 and 20 V.

In a particular embodiment, step i) or the cycle of steps i) and ii) is repeated at least once to form alternating first and second portions.

This aim is also achieved by a structure comprising a base substrate covered with porosified mesas, the porosified mesas being (Al, In, Ga)N or InP mesas or (Al, In, Ga)N/(Al, In, Ga)N or InP/InP mesas, the mesas comprising, from the side faces of the mesas towards the center of the mesas or vice versa, a first portion having a first porosification ratio and a second portion, the second portion having a second porosification ratio higher than the first porosification ratio or the second portion being hollowed out.

In a particular embodiment, the first portion corresponds to the flank of the mesas and the second portion corresponds to the core of the mesas.

In a particular embodiment, the second portion corresponds to the flank of the mesas and the first portion corresponds to the core of the mesas.

According to a particular embodiment, the mesas comprise, from the side faces of the mesas towards the center of the mesas or vice versa, an alternation of first portions and second portions.

According to a particular embodiment, the base substrate comprises a support layer, a first undoped GaN layer, a second doped GaN layer,
a portion of the second doped GaN layer extending into the mesas,
the base substrate may further comprise one or more additional conductive layers, preferably of highly doped GaN, arranged between the first undoped GaN layer and the second doped GaN layer.

According to a particular embodiment, the first porosification ratio is less than 10% and/or the second porosification ratio is greater than or equal to 40%, preferably between 40 and 70%.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 shows a schematic cross-section of a structure comprising an (Al, In, Ga)N/(Al, In, Ga)N or InP/InP mesa, prior to porosification, according to a particular embodiment of the invention;

FIG. 2 shows a schematic cross-section of a structure comprising an (Al, In, Ga)N or InP mesa, prior to porosification, according to another particular embodiment of the invention;

FIG. 3, FIG. 4, FIG. 5, FIG. 6 and FIG. 7 show, schematically and in cross-section, different structures comprising (Al, In, Ga)N or InP mesas or (Al, In, Ga)N/(Al, In, Ga)N or InP/InP mesas, after porosification, according to different particular embodiments of the invention;

FIG. 8 is a graph showing the different phenomena involved (pre-breakdown, porosification and electropolishing) during an anodizing step, as a function of the doping ratio and the applied potential, according to a particular embodiment of the invention;

FIG. 9A and FIG. 9B are scanning electron microscope images of a porosified (Al, In, Ga)N/(Al, In, Ga)N mesa, in side view and cross-section respectively, according to another particular embodiment of the invention;

FIG. 10 is a scanning electron microscope image of a porosified (Al, In, Ga)N mesa, seen in cross-section, according to another particular embodiment of the invention;

FIG. 11 and FIG. 12 are scanning electron microscope views of different porosified (Al, In, Ga)N/(Al, In, Ga)N mesas, in cross-section, according to different particular embodiments of the invention.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 5°.

Between X and Y means that X and Y are included.

The porosity (or porosification) ratio of a material is the ratio of pore volume (void volume) to total material volume.

A porosification ratio is strictly greater than 0% and strictly less than 100%.

Although this is by no means limiting, the invention has particular applications in the field of color microdisplays, and more specifically in the manufacture of red-green-blue pixels.

However, it could also be used in photovoltaics or water electrolysis (also called water splitting), since InGaN absorbs throughout the visible spectrum, and its valence and conduction bands are around the stability range of water, that is the thermodynamic condition required for the water decomposition reaction. Furthermore, it has a large specific surface area, which is particularly advantageous.

The invention may also be of interest for the manufacture of LEDs or lasers emitting at long wavelengths.

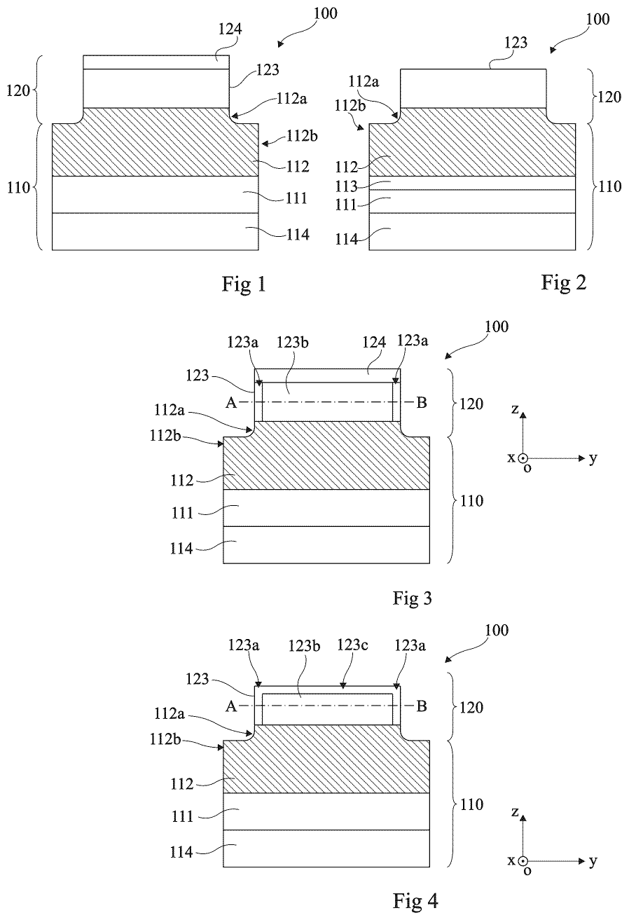

The porosification process described in greater detail below can be applied to structures 100 with (Al, In, Ga)N/(Al, In, Ga)N mesas 120 (FIG. 1) or (Al, In, Ga)N mesas 120 (FIG. 2).

By (Al, In, Ga)N, we mean AlN, AlGaN, InGaN or GaN. Hereinafter, we refer more particularly to porous GaN, but with such a process, it is possible to have, for example, porous InGaN or AlGaN. The dense InGaN layer (in compression) or the dense AlGaN layer (in tension) will relax thanks to a porous structure, whatever its composition.

By (Al, In, Ga)N/(Al, In, Ga)N mesa, we mean that the mesas comprise a layer of highly doped (Al, In, Ga)N 123 to be porosified overlaid by a layer 124 of undoped or lightly doped (Al, In, Ga)N (FIG. 1). In this configuration, epitaxy is carried out on the undoped or lightly doped layer 124. Similarly, by InP/InP mesa, we mean that the mesas comprise a layer of highly doped InP 123 to be porosified overlaid by a layer 124 of undoped or lightly doped InP.

By (Al, In, Ga)N mesa we mean that the mesas comprise a layer of highly doped (Al, In, Ga)N 123 to be porosified. The highly doped (Al, In, Ga)N layer 123 to be porosified is not covered by an undoped or lightly doped (Al, In, Ga)N layer. In this configuration, epitaxy is carried out directly on the highly doped (Al, In, Ga)N layer 123 to be porosified. Similarly, by InP mesa, we mean that the mesas comprise a layer of highly doped InP 123 to be porosified. The highly doped InP layer 123 to be porosified is not covered by an undoped or lightly doped InP layer.

In the following, the process and structure will be described in particular for (Al, In, Ga)N/(Al, In, Ga)N mesas or (Al, In, Ga)N mesas, but the invention can also be applied to InP/InP mesas or InP mesas.

The porosification process comprises the following steps:
a) providing a structure 100 comprising a base substrate 110 covered with mesas 120, the mesas 120 being (Al, In, Ga)N/(Al, In, Ga)N mesas (FIG. 1) or (Al, In, Ga)N mesas (FIG. 2),
b) electrically connect structure 100 and a counter-electrode to a voltage or current generator,
c) immerse structure 100 and counter-electrode in an electrolytic solution,
d) porosifying the mesas 120 electrochemically by performing the cycle consisting of the following steps i) and ii) one or more times:
   i) applying a first potential for a first duration between the structure 100 and the counter-electrode,
   ii) applying a second potential for a second duration between the structure 100 and the counter-electrode.

A multi-stage porosification step with different potentials produces structured mesas with several differently porosified portions in the xOy plane, i.e. parallel to the stack formed by the base substrate and the mesa (FIGS. 2 to 7). For each mesa, the differently porosified portions follow one another from the side faces of the mesa 120 towards the center of the mesa 120.

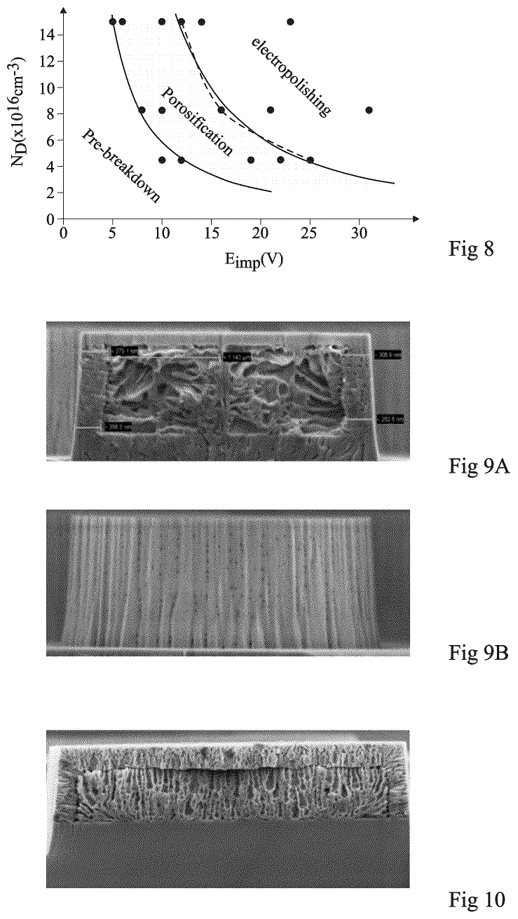

There's no need for different doping in the mesa to modulate porosity. Porosity is modulated as a function of the different potentials applied. Indeed, at a constant doping ratio, depending on the potential applied, different porosity ratios, pore sizes and densities are obtained (see “abacus” in FIG. 8).

At low potential, porosity and pore size are low. This is a nucleation regime (‘pre-breakdown’), leading to the creation of channels. The channels are created from:
the flanks of mesas 120, when the mesas comprise an undoped top layer 124, or
the flanks and top of mesas 120 (i.e. at the level of the sufficiently doped portions in contact with the electrolytic solution) when mesas 120 are not covered by the undoped top layer.

At higher potentials, the porosification regime is reached: porosification propagates in the most conductive zones (in other words, in those portions of the mesa that have not yet been involved in charge-consuming electrochemical reactions).

Several porosified structures can be obtained.

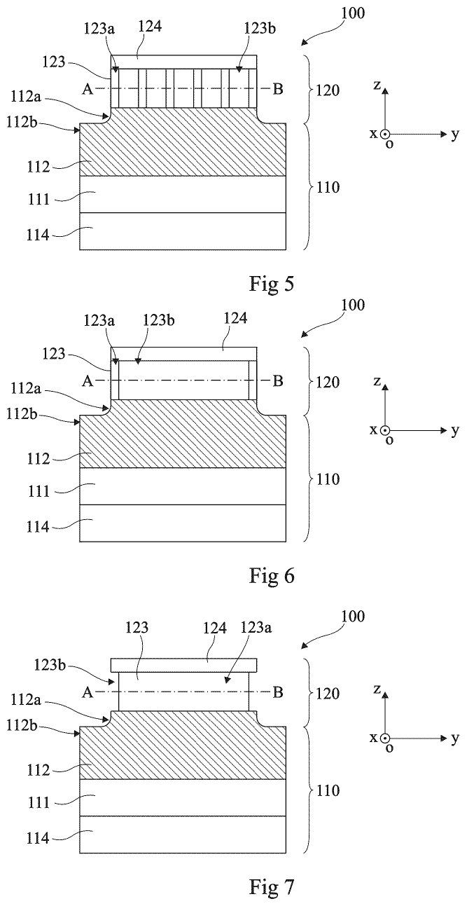

In an alternative embodiment, for example as shown in FIG. 3 or FIG. 4, the mesa 120 has a first porosified portion 123a, with a first porosification ratio, and a second porosified portion 123b, with a second porosification ratio, the first porosification ratio being lower than the second porosification ratio. Preferably, the flanks of the mesa 120 correspond to the first portion 123a. In other words, the core 123b of the mesa is more porosified than the flanks 123a of mesa 120. This results in less porosity on the surface of the flanks, while maintaining a high central porosity. The lower porosity on the sidewalls limits their surface roughness and will therefore have less impact on epitaxy recovery, thus facilitating the implementation of all necessary technological steps (lower volume of chemical solution penetrating the porous structure, less salting-out, better integrity of the structure which is more suitable for receiving a conformal deposit, etc).

Such structures are particularly advantageous because they enable to:
modulate porosity, which plays a key role in In incorporation during InGaN epitaxy,
keep the compliance effect provided by the high porosity at the center of the mesa, and enable In incorporation to match the red emission of InGaN quantum wells (typically above 620 nm).

In the case where the mesas 120 are (Al, In, Ga)N mesas (i.e. where the doped layer 123 is in contact with the electrolyte), the upper portion 123c of the doped layer 123 is also porosified along an axis perpendicular to the mesa/substrate stack (FIG. 4). The porosification ratio of the top 123c of mesa 120 corresponds to the porosification ratio of the flanks of mesas 120.

One advantage of this structure is that the initial epitaxy is simpler, since it is made of a single material (in this case, the GaN or InGaN uid layer is no longer required).

According to another variant, for example shown in FIGS. 6 and 7, mesa 120 has a porosified first portion 123a and a hollowed-out (i.e. material-free) second portion 123b.

The hollowed-out portion 123b may correspond to the central portion of the mesa, with the porosified portion 123a then forming the sides of the mesa. The mesa is drum-shaped (FIG. 6).

Alternatively, as shown in FIG. 7, the hollowed-out portion 123b may correspond to the initial location of the flanks of the mesa 120 and the first porosified portion 123a to the core of the mesa 120. For example, to obtain such a structure, the first potential is located in the electropolishing zone to etch the flanks and reduce the width of the mesa structure. The second potential applied is lower than the first potential to porosify the mesa core.

In another embodiment, as shown in FIG. 5 for example, it is possible to form a structure having mesas 120 with alternating first portions 123a and second portions 123b when the cycle of steps i) and ii) is repeated several times. The second portions 123b may be highly porous or free of material. Such a structure 100 is interesting for micro-displays (‘μ-displays’) because the different porosities induce variable relaxation ratios of the top layer. Such a structure 100 may also be of interest for other photonic applications.

We will now describe the various stages of the process in more detail.

The structure 100 provided in step a) comprises a base substrate 110 covered with mesas 120.

The base substrate 110 comprises in succession (FIGS. 1 and 2):
a support layer 114,
possibly a (Al, Ga)N buffer layer (not shown), particularly in the case of a silicon support layer 114,
a first undoped GaN layer 111,
optionally, an additional highly-doped GaN layer 113,
a second doped GaN layer 112, a first portion 112a of the doped GaN layer 112 extending into the mesas 120 and a second portion 112b of the second doped GaN layer forming part of the substrate 110.

The second doped GaN layer 112 can be non-intentionally doped if the structure includes the additional highly-doped GaN layer 113.

The first portion 112b of the doped GaN layer is common to all mesas.

Each 120 mesa comprises, in succession from the base: the second 112a portion of the 112 doped GaN layer, the third highly-doped GaN layer 123 and, if applicable, the fourth undoped or lightly-doped (Al, In, Ga)N layer 124.

The structure 100 supplied in step a) is, for example, obtained by supplying and then locally etching a stack successively comprising:
a support layer 114 (also called substrate),
optionally, an (Al, Ga)N buffer layer, particularly in the case of a silicon or SiC support layer 114,
a first undoped GaN layer 111,
optionally, an additional highly doped GaN layer 113,
a second GaN layer 112, either doped (GaN n) or not intentionally doped (if the structure includes the additional heavily-doped GaN layer 113),
a third layer of highly doped GaN (GaN n+ or GaN nn) 123, and
if required, an non intentionally doped (nid) or lightly doped fourth layer of AlN, InGaN or GaN (denoted (Al, In, Ga)N) 124.

Preferably, the stack consists of the aforementioned layers. In other words, there are no other layers.

The stack is structured, for example, using photolithography.

The result is a structure 100 comprising a base substrate 110 topped by a plurality of (Al, In, Ga)N/(Al, In, Ga)N mesas 120.

Mesas 120, also known as elevations, are relief elements. They are obtained, for example, by etching a continuous layer or several superimposed continuous layers, so as to leave only a certain number of “reliefs” of this layer or these layers. Etching is preferably carried out with a hard mask, e.g. SiO₂. After the mesas have been etched, this hard mask is removed by a wet chemical process prior to porosification. It is also possible to remove this hard mask after porosification, by exposing it only in the areas used for electrochemical polarization. Advantageously, the mask is removed before the porosification step.

Preferably, the side faces and flanks (lateral portions) of the 120 mesas are perpendicular to this stack of layers.

Mesas can be circular, hexagonal, square or rectangular.

The largest surface dimension of mesas 120 ranges from 500 nm to 500 μm. For example, the largest dimension of a circular surface is its diameter.

Mesa thickness corresponds to the dimension of the mesa perpendicular to the underlying stack.

Mesas 120 can have a pitch of less than 30 μm. The spacing between two consecutive 120 mesas ranges from 50 nm to 20 μm.

Mesas 120 can have identical or different doping levels. The higher the doping level, the greater the porosification at fixed potential. Relaxation of the fourth layer 124 of dense (Al, In, Ga)N depends on the porosification ratio of the mesas. As a result, different quantities of indium can be incorporated during InGaN re-epitaxy on the dense layer 124, thanks to the reduction of the compositional pulling effect (i.e. the pushing of In atoms towards the surface, preventing them from incorporating into the layer). After epitaxy of the complete LED structure, blue, green and red (RGB) mesas can thus be obtained on the same substrate, and in a single growth step, if the distance between the mesas' relaxation levels is sufficient.

The support layer 114 is made of sapphire, SiC or silicon, for example. It could also be made of GaN (‘GaN free standing’).

The thickness of the support layer 114, for example, ranges from 250 μm to 2 mm. The thickness depends on the nature of the support layer 114 and its dimensions. For example, for a 2-inch-diameter sapphire support layer, the thickness may be 350 μm. For a 6-inch-diameter sapphire support layer, the thickness may be 1.3 mm. For a silicon support layer 200 mm in diameter, the thickness may be 1 mm.

In the case of a silicon support layer 114, an (Al, Ga)N buffer layer is advantageously interposed between the support layer 114 and the nid GaN layer 111.

The first layer 111 is a nid GaN layer. This is an non intentionally doped (nid) layer so as not to be porosified. non intentionally doped (In) GaN means a concentration of less than 5^{e}17 at/cm³ for InGaN and 5^{e}17 at/cm³ for GaN.

The first nid GaN layer 111 is, for example, between 500 nm and 5 μm thick. Advantageously, its thickness is between 1 and 4 μm to absorb the stresses associated with the lattice mismatch between the GaN and the substrate.

For InP, the undoped or lightly doped 124 InP layer (n−) has, for example, a doping of less than 1^{e}17 at·cm⁻³ and the heavily doped 123 InP layer (n+) has, for example, a doping of more than 5^{e}18 at·cm⁻³.

In a particularly advantageous embodiment, the 100 structure includes an additional, highly-doped GaN layer 113 (shown only in FIG. 2, but which may be present in all structures) arranged between the first, undoped GaN layer 111 and the second, doped GaN layer 112. The result is a tri-layer comprising a highly doped GaN layer covered by the second doped layer 112 and the third highly doped GaN layer 123 to be porosified. The second doped layer 112 protects the underlying additional heavily doped layer 113 and ensures contact during porosification. In this way, the additional layer 113 is not in contact with the solution.

The highly doped additional layer 113 ensures lateral charge conduction in the structure. For example, the doping level of the heavily doped GaN additional layer is between 5.10¹⁸ at/cm³ and 2.1019 at/cm³, preferably between 5.10¹⁸ at/cm³ and 1.5.1019 at/cm³, even more preferably between 8.10¹⁸ at/cm³ and 1.1019 at/cm³. Advantageously, this layer is thick (typically between 0.5 μm and 5 μm and preferably between 1 and 2 μm). Higher thicknesses can be obtained on sapphire. The result is a highly conductive buried layer, thanks to a high level of doping and a significant layer thickness. The doping thickness will be adapted to ensure sufficient lateral conduction. In step d), conduction takes place via this additional, highly doped buried layer. As it is highly conductive, it limits edge/center effects.

The charges pass through the second doped layer 112 and then onto the additional, highly doped layer 113, which acts as a conduction highway and supplies all the mesas present on the substrate. In step d), the second doped layer 112 protects the highly doped additional layer 113 from porosification. In this way, each mesa 120 is in the same electrical configuration for uniform porosification, whatever the size and position of the mesa on the plate (edge or center).

The second layer 112 can be a doped or lightly doped GaN layer, depending on the architecture of the structure. By doped GaN is meant a concentration greater than 1.1017 at/cm³, preferably greater than 5.1017 at/cm³, more preferably between 5.1017 at/cm³ and 2.10¹⁸ at/cm³. As previously indicated, in the case of a trilayer (i.e. if layer 113 is present), layer 112 can be doped GaN or nid-GaN.

The second GaN layer 112 is, for example, between 200 nm and 1 μm thick, preferably between 400 and 700 nm. It must be sufficiently electrically conductive to be able to make contact with this layer during the electrochemical anodizing step. The minimum thickness varies according to the doping level. This electrically conductive layer is electrically connected to the voltage or current generator.

The third layer 123 is a highly doped GaN layer. Highly doped GaN means a concentration greater than 5.10¹⁸ at/cm³, preferably greater than 8.10¹⁸ at/cm³, or even greater than 1019 at/cm³. It has, for example, a doping ten times higher than the second layer 112. It has a thickness, for example, of between 200 nm and 2 μm. Preferably from 500 nm to 1 μm.

The fourth layer 124 is a non intentionally doped or lightly doped (Al, In, Ga)N layer. Lightly doped (Al, In, Ga)N means doping between 5.1017 at·cm³ and 1.10¹⁸ at·cm³. Non-doped refers to a doping level of less than 5^{e}17 at/cm³ or even less than 1^{e}17 at/cm³.

This can be an AlN, AlGaN, InGaN or GaN layer. It is, for example, between 10 nm and 200 nm thick, preferably between 50 nm and 200 nm. The doping is sufficiently low so that this layer is electrically insulating. It is not porosified in step d).

This layer 124 is little or not at all affected by porosification and serves as a seed for growth restart. This layer 124 is continuous to ensure the quality of the repitaxial layer, of an (In, Ga)N layer for example, on the structure.

The doping of the various layers mentioned above is chosen according to the voltage applied during porosification.

In particular, they will be chosen on the basis of an “abacus” such as that shown in FIG. 8. This “abacus” makes it possible to define the respective doping ratios so that, at a given potential, there is selectivity between the heavily doped zone and the lightly doped zone. For a given potential, the doping ratio of the second layer 112 must be in the ‘pre-breakdown’ region so that the second layer 112 is not porosified during step d). The doping ratio of the third layer 123 must be in the ‘porosification’ region for the third layer 123 to be porosified, or in the ‘electropolishing’ zone for the third layer 123 to be etched.

In the following, we describe n-type doping, but it could also be p-type doping. The electrochemical conditions (e.g. potential) will be chosen for such doping.

By way of illustration and non-limitation, according to an alternative embodiment, the structure 100 to be porosified may comprise:
a base substrate 110 successively comprising: a sapphire or silicon support layer 114, optionally an (Al, Ga)N buffer layer, a first undoped GaN layer 111 of 4 μm, a first portion 112a of the second doped GaN layer 112 of 500 nm (1.10¹⁸ at/cm³),
mesas 120 of (Al, In, Ga)N/(Al, In, Ga)N successively comprising: a second portion 112b of the second doped GaN layer 112 of 100 nm (1.10¹⁸ at/cm³), a third highly doped GaN layer 123 of 800 nm (1.1019 at/cm³), and, if required, a nid layer (Al, In, Ga)N of 100 nm.

An additional 2 μm (1.1019 at/cm³) layer 113 of highly doped GaN can be positioned between the first undoped GaN layer 111 and the first portion 112a of the second doped GaN layer 112.

In step b), the structure 100 and a counter-electrode (CE) are electrically connected to a voltage or current generator. The device acts as a working electrode (WE). Hereinafter, it will be referred to as a voltage generator, but it could also be a current generator enabling a current to be applied between the device and the counter-electrode.

Contact is made on structure 100.

In particular, contact can be made on the base substrate 110, especially on the second doped GaN layer 112. Preferably, the contact can be made on the bottom of the mesas 120, at the level of the second portion 112b of the second layer 112, which makes it possible to use the etching step to also make the contacts.

The recontact zone can also be topped with a metal layer to improve contact for electrochemical polarization. This contact can be removed after porosification and before epitaxy.

The counter-electrode is made of an electrically conductive material, such as a metal with a large surface area, and is inert to the electrolyte chemistry, such as a platinum grid.

In step c), the electrodes are immersed in an electrolyte, also known as an electrolyte bath or electrolyte solution. The electrolyte can be acidic or basic. The electrolyte is, for example, oxalic acid, KOH, HF, HNO₃, NaNO₃ or H₂SO₄. It can also be a mixture of these, for example a mixture of oxalic acid and NaNO₃ to enhance kinetics.

In step d), the mesas are porosified.

The first potential E1 is different from the second potential E2. The first potential E1 is preferably lower than the second potential E2.

Potential modulation during the anodizing process enables the mesa flanks to be porosified very lightly initially, followed by increased porosification and even etching of the mesa center. The first low-potential step (E1) creates channels. These channels then lead the electrolyte to the center of the mesa, which under the effect of a second potential (E2 with E2>E1) porosifies to a greater extent than the flanks, or is even electropolished. The result is a mesa with a highly porous or material-free center and low-porosity sides.

When iterating steps i) and ii), it would also be possible to use different potentials and/or durations from those used in the first cycle of steps i) and ii). Preferably, the same potentials are used.

Depending on the width of the mesas, the number of iterations, potentials and potential application times can be adapted. It is possible to modulate the number of first portions 123a (low porosity) and second portions 123b (high porosity or hollow), as well as their widths.

Applied potentials can range from 1 to 50V. Preferably between 3 and 20V.

For example, the first potential is between 3 V and 12 V and/or the second potential is between 5 and 20 V.

On sapphire, the first potential is preferably between 3.5 and 4.5 V and/or the second potential is between 7 and 10 V.

On silicon, the first potential is preferably between 7 and 10 V and/or the second potential is preferably between 14 and 17 V.

The potential is chosen according to the doping levels of the different layers, in order to achieve the desired selectivity. It is applied, for example, for a period ranging from a few seconds to several hours.

Porosification is complete when there is no longer any current at an imposed potential. At this point, the entire doped structure is porosified and the electrochemical reaction stops.

It is also possible to achieve incomplete porosification and retain an unporosified, unengraved core. The non-porosified core is surrounded on either side by the second portion, which forms a highly porous intermediate zone, and then by the first portion, which forms low-porosity sides.

The electrochemical anodizing step can be activated by irradiation at the wavelength corresponding to the material's gap (e.g. UVA for GaN, UVB and UVC for AlGaN depending on the Al content).

Advantageously, at the end of the porosification step, the entire volume of the third highly-doped GaN layer 123 is porosified.

The first portion 123a is lightly porous. The first porosification ratio is preferably less than 10%. It is, for example, between 2 and 10%.

The second portion 123b is hollow or highly porous. The second porosification ratio is preferably at least 40%. It is, for example, between 40% and 70%.

The largest dimension (the height) of the pores can vary from a few nanometers to a few micrometers. The smallest dimension (diameter) can vary from a few nanometers to a hundred nanometers, in particular from 30 to 70 nm.

The porosifications obtained (porosity ratio, also known as porosification ratio, and pore size) depend on the doping of the layer and the process parameters (applied voltages, times, nature and concentration of the electrolyte, chemical post-treatment or annealing). Variation in porosification enables the incorporation/segregation ratio to be controlled. Porosification, and in particular pore size and morphology, can be varied at a later stage, when epitaxy is resumed, depending on the temperature applied.

The process can also include a step in which the highly porous portion 123b is etched by a solution, in particular an alkaline solution, preferably KOH or tetramethylammonium hydroxide (TMAH).

Advantageously, the process includes a subsequent step e) in which epitaxy is performed on the 120 mesas, resulting in an at least partially relaxed, and preferably fully relaxed, epitaxial layer.

The relaxation percentage corresponds to:

Δa/a=(a_{c2}−a_{c1})/a_{c1}
with a_{c1}, the lattice parameter of the starting layer on which epitaxy is started (i.e. the lattice parameter of layer 124), and
a_{c2} the lattice parameter of the relaxed layer,

The layer is 100% relaxed if a_{c2} corresponds to the lattice parameter of the bulk material of the same composition as the re-epitaxial layer.

When a_{c1}=a_{c2} the layer is said to be constrained.

Partially relaxed is defined as a relaxation percentage greater than 50%.

Re-epitaxy can be used, for example, to form re-epitaxial LEDs.

Re-epitaxy can be carried out on the fourth, nid or lightly doped layer 124 of mesas 120. As this layer is not porosified during the electrochemical anodizing step, it remains continuous and dense. This facilitates epitaxy rework and improves the durability of the epitaxial layer. Defects due to pore coalescence are avoided.

Re-epitaxy can also be carried out on the upper portion 123c of the porosified doped layer 123 of the mesas. As this layer is only lightly porosified, epitaxy can be easily carried out.

The epitaxial layer produced in step e) is preferably made of gallium nitride or indium gallium nitride.

### Illustrative and Non-Limiting Examples of Different Embodiments

Several structures have been built.

### 1^{ère} Restructure

The first structure to be porosified is one such as that shown in FIG. 1, with (Al, In, Ga)N/(Al, In, Ga)N mesas, particularly InGaN/GaN or GaN/GaN mesas.

The first stage at low potential (E1=4.5 V for 300 s) creates channels in the flanks, which become less conductive. The channels serve to conduct the electrolyte towards the center of the mesa when the second potential is applied. Under the effect of the second potential, E2, which is stronger than the first potential (E2=11 V for 250 s), the center of the mesa porosifies to a greater extent than the flanks. The porosification reaction takes place at the interface between the electrolyte and the highly conductive or highly doped zone, i.e. in the central zone of the mesa.

Potential modulation during anodizing results in very low porosification of the mesa flanks, followed by higher porosification of the mesa center (FIGS. 9A and 9B).

### 2^{th} Structure

The second structure to be porosified corresponds to one such as that shown in FIG. 2. The structure comprises (Al, In, Ga)N mesas, and more particularly Si-doped GaN mesas. In this structure, there is no nid layer covering the mesas.

As with the first structure, two different potentials are applied. The first potential E1=3V is applied for 130 s and the second potential E2 is applied for 100 s. By applying two different potentials, a very low-pore layer is formed on the top and sides of the mesas. The pore size is very small (typically less than 10 nm) and compatible with defect-free GaN epitaxy (since lateral GaN epitaxy is strong). Here, the multi-potential process makes it possible to obtain a core/shell mesa with a highly porous core and a very low-porosity shell from an n-doped GaN mesa (FIG. 10).

The thickness of the low-porosity envelope depends on the application time of the first potential E1<E2. In the case of structure n°2, 130s at E1 produces an envelope of 200 to 250 nm. This time can be reduced and thinner envelopes of the order of 50 to 100 nm can be produced.

This process results in homogeneous vertical porosification across the entire mesa, except for the low-porosity envelope. The core has a porosity of at least 40%, with a dendritic morphology.

Such vertical relaxation is conducive to relaxation. It can improve the relaxation of epitaxial top layers, whether in InGaN for red emission or in AlGaN for UV applications.

### 3^{rd} Structure

The third structure to be porosified corresponds to a structure such as that shown in FIG. 1. The structure features (Al, In, Ga)N/(Al, In, Ga)N mesas, and more specifically GaN/GaN mesas.

Two potentials are applied to the structure. Potential E2 is higher than potential E1. Potential E2 lies in the electro-polishing zone of the material. As a result, the center of the mesa is not porosified but etched. An additional chemical etching step, in particular alkaline etching (e.g. TMAH or KOH), can be used to etch any material remaining in the center of the mesa, thus forming a cavity.

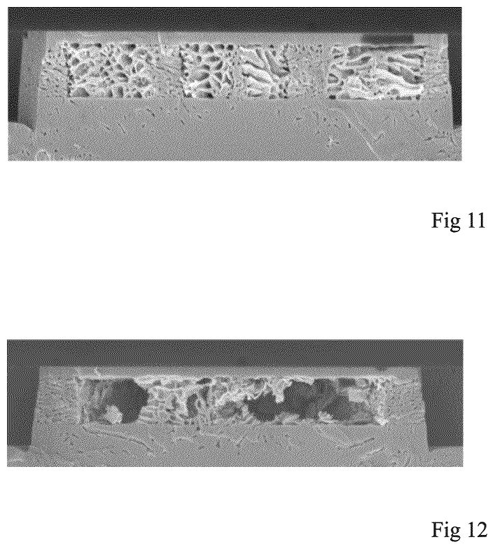

The result is an InGaN or GaN membrane (but it could also be an AlGaN membrane) with a thickness ranging from 50 nm to 200 nm suspended above a cavity with lightly porous GaN walls of dimensions ranging from 1 μm to a few μm, 3 μm for example (FIG. 11).

Stress relaxation on this GaN or InGaN layer is maximized, since the layer on which the epitaxy is performed is uncoupled from its growth substrate, which imposed its lattice parameter. This new type of structure (a sort of drum) is particularly interesting for photonic devices, but also for MEMS-type devices.

### 4^{th} Structure

The fourth structure to be porosified corresponds to a structure such as that shown in FIG. 1. The structure features (Al, In, Ga)N/(Al, In, Ga)N mesas, and more specifically GaN/GaN mesas.

In this example, the first potential E1 is applied for 200 s and the second potential E2 is applied for 120 s. The cycle of applying potentials E1 and E2 is repeated once. The resulting structure is shown in FIG. 12.

Depending on the width of the mesa, it is possible to adapt the number of iterations and the application time of the potentials to modulate the number of alternating low-porosity zones and porous zones, as well as their width.

Various embodiments and variants have been described. The person skilled in the art will understand that certain features of these various embodiments and variants could be combined, and other variants will become apparent to the person skilled in the art.

Finally, the practical implementation of the embodiments and variants described is within the reach of the person skilled in the art on the basis of the functional indications given above.

1. Process for porosifying a structure comprising a base substrate covered with mesas, the mesas being (Al, In, Ga)N or InP mesas or (Al, In, Ga)N/(Al, In, Ga)N or InP/InP mesas, the mesas being electrochemically porosified according to the following cycle of steps:
i) applying a first potential for a first duration,
ii) applying a second potential for a second duration,
whereby porosified mesas are obtained, the mesas comprising, from the side faces of the mesas towards the center of the mesas or vice versa, a first portion having a first porosification ratio and a second portion, the second portion having a second porosification ratio higher than the first porosification ratio or the second portion being hollowed out.

2. Process according to claim 1, in which the first potential is lower than the second potential.

3. Process according to claim 1, wherein the first potential is between 3 V and 12 V and/or wherein the second potential is between 5 and 20 V.

4. Process according to claim 1, in which step i) or the cycle of steps i) and ii) is repeated at least once so as to form an alternation of first portions and second portions.

5. Structure comprising a base substrate covered with porosified mesas, the porosified mesas being (Al, In, Ga)N or InP mesas or (Al, In, Ga)N/(Al, In, Ga)N or InP/InP mesas,
the mesas comprising, from the side faces of the mesas towards the center of the mesas or vice versa, a first portion having a first porosification ratio and a second portion, the second portion having a second porosification ratio higher than the first porosification ratio or the second portion being hollowed out,
the first portion corresponding to the flank of the mesas and the second portion corresponding to the core of the mesas, or
the second portion corresponding to the flank of the mesas and the first portion corresponding to the core of the mesas, the second portion having a second porosification ratio greater than the first porosification ratio, or
the mesas comprising, from the side faces of the mesas towards the center of the mesas or vice versa, an alternation of first portions and second portions.

6. Structure according to claim 5, in which the first portion corresponds to the flank of the mesas and the second portion corresponds to the core of the mesas.

7. Structure according to claim 5, in which the second portion corresponds to the flank of the mesas and the first portion corresponds to the core of the mesas.

8. Structure according to claim 5, in which the mesas comprise, from the side faces of the mesas towards the center of the mesas or vice versa, an alternation of first portions and second portions.

9. Structure according to claim 5, wherein the base substrate comprises a support layer, a first undoped GaN layer, a second doped GaN layer,
a portion of the second doped GaN layer extending into the mesas,
the base substrate may further comprise one or more additional conductive layers, preferably of highly doped GaN, arranged between the first undoped GaN layer and the second doped GaN layer.

10. Structure according to claim 5, wherein the first porosification ratio is less than 10% and/or wherein the second porosification ratio is greater than or equal to 40%, preferably between 40 and 70%.
